(19) United States
(12) Patent Application Publication
(10) Pub. No.: US 2012/0088345 A1
(43) Pub. Date: Apr. 12, 2012

(54) METHOD OF FORMING SILICIDE FOR CONTACT PLUGS

(76) Inventors: Yi-Wei Chen, Tai-Chung Hsien (TW); Kuo-Chih Lai, Tainan City (TW); Nien-Ting Ho, Tainan City (TW); Chien-Chung Huang, Taichung County (TW)

(21) Appl. No.: 12/902,149

(22) Filed: Oct. 12, 2010

(51) Int. Cl. H01L 21/336

(52) U.S. Cl. 438/301; 257/E21.409

(57) ABSTRACT

A method for forming silicide is provided. First, a substrate is provided. Second, a gate structure is formed on the substrate which includes a silicon layer, a gate dielectric layer and at least one spacer. Then, a pair of source and drain is formed in the substrate and adjacent to the gate structure. Later, an interlayer dielectric layer is formed to cover the gate structure, the source and the drain. Afterwards, the interlayer dielectric layer is selectively removed to expose the gate structure. Next, multiple contact holes are formed in the interlayer dielectric layer to expose part of the substrate. Afterwards, the exposed substrate is converted to form silicide.

### BACKGROUND OF THE INVENTION

1. Field of the Invention

The present invention generally relates to a method for forming silicide. In particular, the present invention is directed to a method for forming silicide for use in a contact plug to avoid a leaking current due to the piping problem of the silicide.

2. Description of the Prior Art

A semiconductor device is widely used in all kinds of electronic products, such as computers, mobile phones, etc. To put it in a simple way, in a typical semiconductor element a gate is constructed on a silicon substrate and a pair of source and drain with dopants is formed in the substrate at two sides of the gate structure by ion implantation. The gate, the source and the drain together form a typical semiconductor element. At the moment, the gate, the source and the drain still need to be electrically connected to an outer circuit. Generally speaking, a metal is usually chosen to be the electric media for the electrical connection to the outer circuit because a metal usually has very low electric resistance.

Due to the very large contact resistance existing between the silicon substrate and the metal, the simple ohmic contact is adverse to the electric performance of the elements so an additional silicide which is disposed between the silicon substrate and the metal serving as the electric media is needed to lower the contact resistance. The silicide itself not only has low enough resistance to lower the contact resistance due to the simple ohmic contact between the silicon substrate and the metal, but also improves the electric performance of the elements.

On the other hand, in order to increase the carrier mobility in the substrate, a stress layer is also intended to be formed in or on the substrate to obtain an improved carrier mobility by adjusting the stress level of the stress layer. However once the stress engineering is taken into consideration, the current leakage owing to the silicide rises, in particular the leaking current caused by the piping defect of silicide.

Still, when the metal gate process or the high-K process is taken into consideration, the stability of silicide is not concrete anymore, in particular for the gate-last process because the silicide is formed before the metal gate. When the metal gate is formed later than the silicide, there are possible thermal budget concern, cross-contamination and defect issues.

In order to solve the problem of the leaking current caused by the piping defect of silicide as well as the problems of thermal budget concern, cross-contamination and defect issues when the metal gate is formed later than the silicide, a novel method for forming silicide is still needed, in particular a novel method for forming silicide for use in a contact plug, to solve the problems and to gain benefits of process integration at the same time.

### SUMMARY OF THE INVENTION

The present invention therefore proposes a novel method for forming silicide, in particular for use in a contact plug. The method of the present invention may solve the problem of the current leakage caused by the piping defect of the silicide. In addition to this, the method of the present invention may also solve the problems such as the thermal budget concern, cross-contamination and defect issues when the metal gate is formed later than the silicide. Furthermore, the method of the present invention may also gain benefits of process integration at the same time.

The present invention in a first aspect proposes a method for forming silicide, in particular for use in a contact plug. First, a substrate is provided. Second, a gate structure is formed on the substrate which includes a silicon layer, a gate dielectric layer and at least one spacer. Then, a pair of source and drain is formed in the substrate and adjacent to the gate structure. Later, an interlayer dielectric layer is formed to cover the gate structure, the source and the drain. Afterwards, the interlayer dielectric layer is selectively removed to expose the gate structure. Next, multiple contact holes are formed in the interlayer dielectric layer to expose part of the substrate. Afterwards, the exposed substrate is converted to form the silicide. In one embodiment of the present invention, the way to convert the substrate to form the silicide may be that the contact holes are filled with a contact metal which is in direct contact with the source and the drain, then an annealing step is carried out to react the contact metal with the substrate to yield the silicide. In another embodiment of the present invention, a source contact plug and a drain contact plug are formed in the multiple contact holes and in direct contact with the silicide.

The present invention in a second aspect proposes a method for forming silicide, in particular for use in a contact plug. First, a gate structure is provided. The gate structure is disposed on a substrate and includes a dummy gate. Second, a pair of source and drain is formed in the substrate and adjacent to the gate structure. Then, an interlayer dielectric layer is formed to cover the source and the drain and to expose the gate structure. Next, the dummy gate is selectively removed. Later, multiple contact holes are formed in the interlayer dielectric layer to expose the source and the drain. Afterwards, the contact holes are filled with a contact metal which is in direct contact with the source and the drain. Thereafter, an annealing step is carried out to react the contact metal with the substrate to yield the silicide. In one embodiment of the present invention, a source contact plug and a drain contact plug are formed in the contact holes and in direct contact with the silicide. In another embodiment of the present invention, a metal gate which includes a gate metal and a gate oxide is formed to replace the dummy gate before the contact holes are formed. In still another embodiment of the present invention, the contact metal is used to replace the dummy gate to form a metal gate.

The silicide formed by the method of the present invention is restricted to where it is needed, so the method of the present invention may solve the problem of the leaking current caused by the piping defect of the silicide. In addition to this, the method of the present invention may also solve the problem such as the thermal budget concern, cross-contamination and defect issues when the metal gate is formed later than the silicide. Furthermore, the method of the present invention may also gain benefits of process integration at the same time.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate an example of the method of the present invention.

FIGS. 7-12 illustrate another example of the method of the present invention.

### DETAILED DESCRIPTION

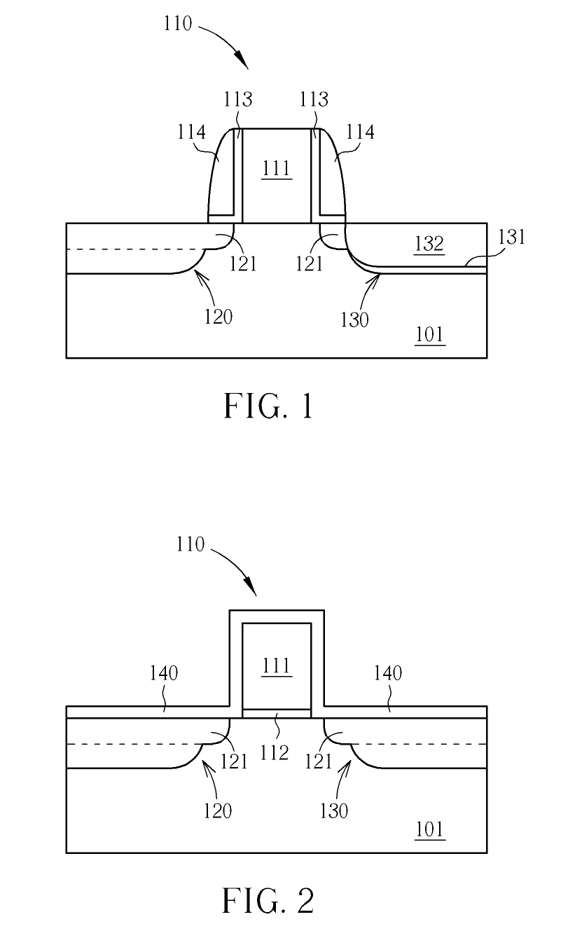

The present invention in one aspect provides a method for forming silicide, in particular for use in a contact plug, to solve the problem of the leaking current caused by the piping defect of the silicide. Please refer to FIGS. 1-6, illustrating an example of the method of the present invention. First, a substrate 101 is provided. The substrate 101 may be a semiconductor substrate, such as Si. Second, a gate structure 110 is formed on the substrate 101. The gate structure 110 has a silicon layer 111, a gate dielectric layer 112 and a spacer. The spacer of the gate structure 110 may be a single spacer or a composite spacer. The composite spacer of the gate structure 110 may be optionally removed in the method or becomes part of the permanent structure.

In addition, as shown in FIG. 1, a pair of source 120 and drain 130 is formed at two sides of the gate structure 110. If a stress is needed on the gate channel, at least one of the source 120 and drain 130 has an epitaxial structure including Si and other material(s). The source 120 and the drain 130 are respectively disposed in the substrate 101 and adjacent to the gate structure 110. The steps to form the source 120 and drain 130 may be related to the formation of the gate structure 110.

For example, when the first spacer 113 of the gate structure 110 is completed, the gate structure 110 itself is used as a mask to carry out a lightly doping procedure to form a set of LDD regions 121 at two sides of the gate structure 110. After that, when the second spacer 114 of the gate structure 110 is completed, a source and drain doping procedure is carried out to form a set of source 120 and drain 130 at two sides of the gate structure 110. Later, at least one of the first spacer 113 and the second spacer 114 may be optionally removed. FIG. 1 illustrates that the gate structure 110 has a composite spacer, i.e. the first spacer 113 and the second spacer 114.

If a stress is needed on the gate channel, at least one of the first spacer 113 and the second spacer 114 may be optionally removed, then an optional stress layer 140 which covers the gate structure 110, the source 120 and drain 130 is formed. Or, at least one of the source 120 and the drain 130 has a recess structure so a suitable epitaxial material fills it to form the stress layer 140. Or both ways are done together. If an etching-stop layer is needed, the etching-stop layer 140 which covers the gate structure 110, the source 120 and drain 130 is formed after the source 120 and drain 130 are done. In one embodiment of the present invention, the stress layer 140 may also serve as the etching-stop layer 140. FIG. 2 illustrates the stress layer 140 serves as an etching-stop layer.

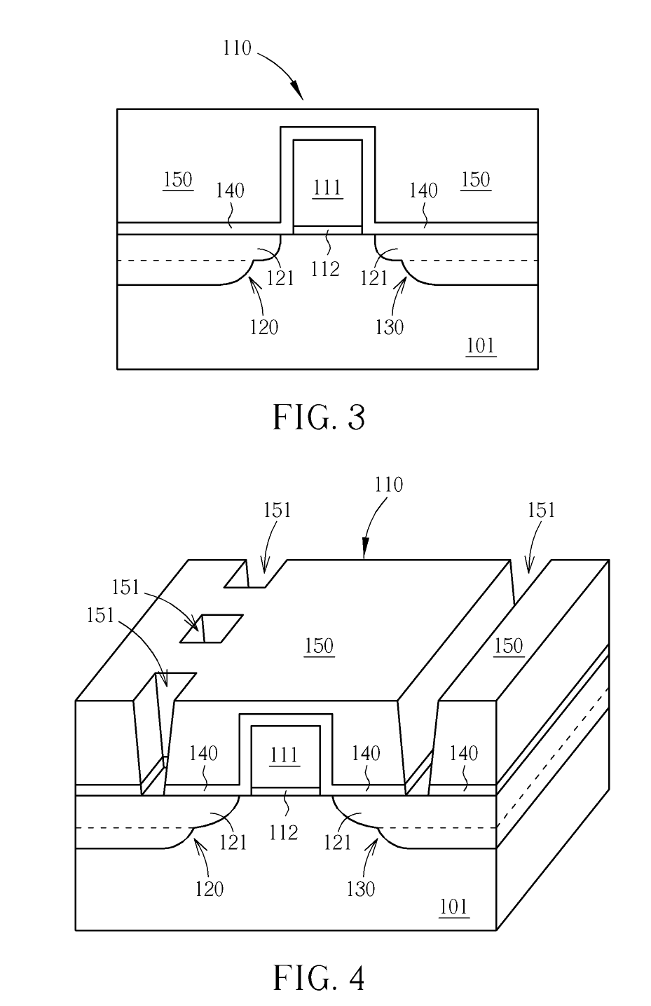

Then, as shown in FIG. 3, an interlayer dielectric layer 150 is formed. The interlayer dielectric layer 150 covers the ready gate structure 110, the source 120 and drain 130 and the optional stress layer 140 or the etching-stop layer 140. The interlayer dielectric layer 150 usually includes a single insulting material or the combination of various insulting materials, such as silicon oxide, nitride, carbide, a high-k material. First, the interlayer dielectric layer 150 is completely deposited on the ready gate structure 110, the source 120 and drain 130, then some of the interlayer dielectric layer 150 is removed, such as by chemical mechanical polishing to expose some of the Si layer 111 in the interlayer dielectric layer 150.

Later, as shown in FIG. 4, the interlayer dielectric layer 150 is selectively removed to form the needed contact holes 151. If any one of the stress layer 140 or the etching-stop layer 140 is present, the contact holes 151 penetrate the stress layer 140 or the etching-stop layer 140 as well to expose part of the substrate 101, usually the source 120 and drain 130 under the interlayer dielectric layer 150 to form the needed electrical connection. The steps to form the contact holes 151 may be that, a lithographic procedure goes with an etching procedure to obtain the contact holes 151 of needed shapes or sizes. For example, as shown in FIG. 4, the contact holes 151 may be in a shape of a single square or of a slot. In addition, the shape of the contact holes 151 of the source 120 and drain 130 may be different, and the size of the contact holes 151 of the source 120 and drain 130 may be different, too.

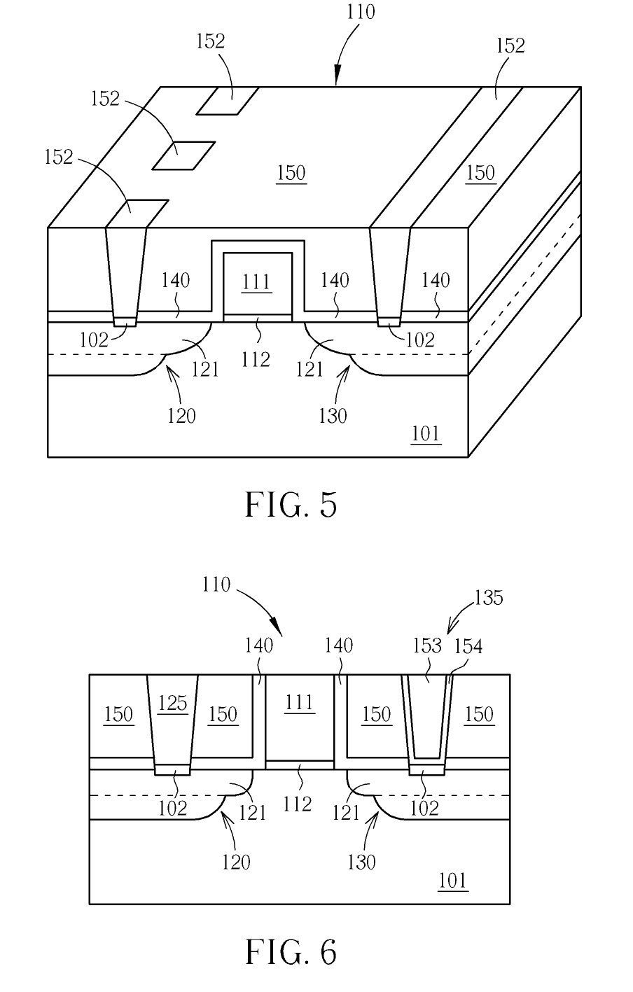

Afterwards, as shown in FIG. 5, the substrate 101 reacts with a suitable metal to form the needed silicide 102. The ways to form the needed silicide 102 may be that, first, a suitable contact metal 152, such as Ni, Co or Ti, is used to fill the contact holes 151 so that the contact metal 152 is in direct contact with the source 120 and the drain 130. Then, an annealing step is carried out to react the contact metal 152 with the substrate 101 to yield the silicide 102. The excessive and unreacted contact metal 152 may be optionally removed. There may be an optional annealing step following the removal of the unreacted contact metal 152 to further lower the electrical resistance of the silicide. Optionally, the contact metal 152 may be in direct contact with the Si layer 111 in the gate structure 110 so that in the following annealing step the contact metal 152 also reacts with the Si layer 111 to yield the silicide 102.

After the silicide 102 is finished, a source contact plug 125 and a drain contact plug 135 are formed in the contact holes 151, as shown in FIG. 6. The source contact plug 125 and the drain contact plug 135 are respectively disposed in the contact holes 151 and in direct contact with the previously formed silicide 102. The ways to form the source contact plug 125 and the drain contact plug 135 may be that, for example, a suitable plug metal 153, such as W, fills the contact holes 151. Optionally, at least two plug materials such as a plug metal 153 and a barrier material 154, are used to form at least one of the source contact plug 125 and the drain contact plug 135. The forming parameters for the barrier material 154, such as materials, thickness may be adjusted to form a maximized stress effect. The plug metal for filling the source and drain may be the same or different.

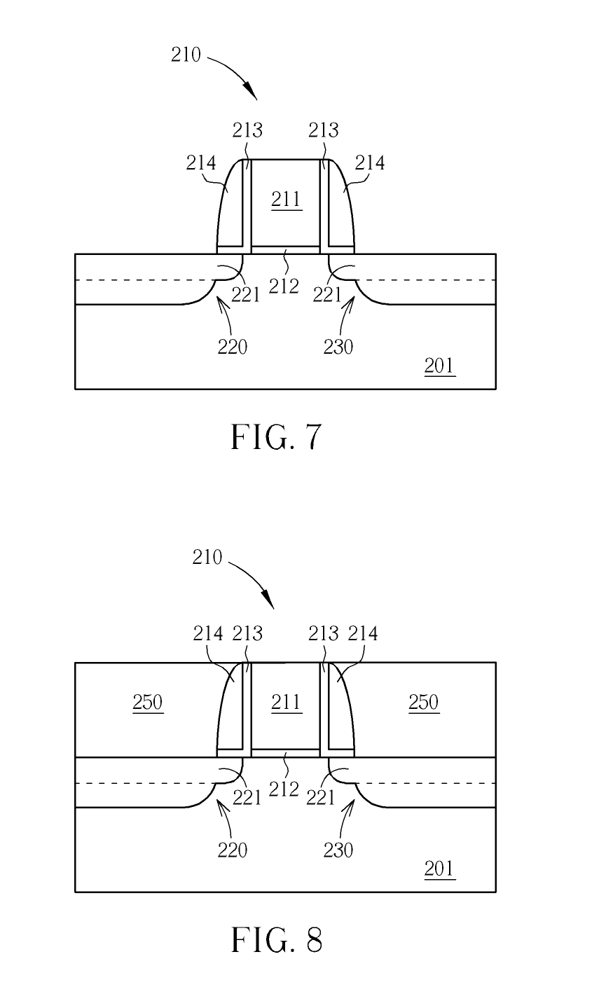

The present invention in another aspect provides a method for forming silicide, in particular for use in a contact plug, to solve the problem of the leaking current caused by the piping defect of the silicide. Please refer to FIGS. 7-12, illustrating another example of the method of the present invention. First, a substrate 201 is provided. The substrate 201 may be a semiconductor substrate, such as Si. Second, a gate structure 210 is formed on the substrate 201. The gate structure 210 may be a Si gate structure or a metal gate structure. If the gate structure 210 is a metal gate structure, in one aspect the high-k gate dielectric layer 212 may have been already formed before the dummy gate 211 is formed. In another aspect, the high-k gate dielectric layer 212 is not formed until the dummy gate 211 is removed in advance, then the metal gate is continued.

Accordingly, the gate structure 210 may include optional gate dielectric layer 212. For example, a single layer of silicon oxide, a composite of silicon oxide and high-k dielectric layer or a composite of silicon oxide, high-k dielectric layer and other insulating material(s). The gate structure 210 may include an optional metal etching barrier layer, a dummy gate 211, a pad oxide layer, a pad oxynitride layer and a spacer. The metal etching barrier layer is usually disposed between the dummy gate 211 and the high-k gate dielectric layer 212. If the gate structure 210 is a metal gate structure, the dummy gate 211 may be amophorous Si, poly-Si, doped poly-Si or SiGe. The spacer of the gate structure 210 may be a single spacer or a composite spacer. For instance, the spacer of the gate structure 210 is a single spacer 213. The composite spacer of the gate structure 210 may be optionally removed in the method or becomes part of the permanent structure. The pad oxide layer and the pad oxynitride layer may be formed when the dummy gate 211 is formed.

In addition, as shown in FIG. 7, a pair of source 220 and drain 230 is formed at two sides of the gate structure 210. If a stress is needed on the gate channel, at least one of the source 220 and the drain 230 has an epitaxial structure of Si and other material(s) to confer the stress. The source 220 and the drain 230 are respectively disposed in the substrate 201 and adjacent to the gate structure 210. The steps to form the source 220 and drain 230 may be related to the formation of the gate structure 210. For example, when the spacer 213 of the gate structure 210 is completed, the gate structure 210 itself is used as a mask to carry out a lightly doping procedure to form a set of LDD regions 221 at two sides of the gate structure 210. After that, when the second spacer 214 of the gate structure 210 is completed, a source 220 and a drain 230 doping procedure is carried out to form a set of source 220 and drain 230 at two sides of the gate structure 210. Optionally, at least one of the first spacer 213 and the second spacer 214 may be removed.

Similarly, in addition to a recessed structure filled with an epitaxial material, a covering stress layer may be formed, or both ways are done together. If a higher stress is needed to be applied on the gate channel, at least one of the first spacer 213 and the second spacer 214 may be removed then the optional stress layer which covers the gate structure 210, the source 220 and drain 230 is formed. If an etching-stop layer is needed, the etching-stop layer which covers the gate structure 210, the source 220 and drain 230 is formed after the source 220 and drain 230 are done. In one embodiment of the present invention, the stress layer may also serve as the etching-stop layer.

Then, as shown in FIG. 8, an interlayer dielectric layer 250 is formed. The interlayer dielectric layer 250 covers the ready gate structure 210, the source 220 and drain 230 and the optional stress layer or the etching-stop layer. The interlayer dielectric layer 250 usually includes a single insulting material or the combination of various insulting materials, such as silicon oxide, nitride, carbide, a high-k material. For instance, the interlayer dielectric layer 250 is completely deposited on the ready gate structure 210, the source 220 and drain 230, then some of the interlayer dielectric layer 250 is removed, such as by chemical mechanical polishing to expose some of the dummy gate 211 in the gate structure 210.

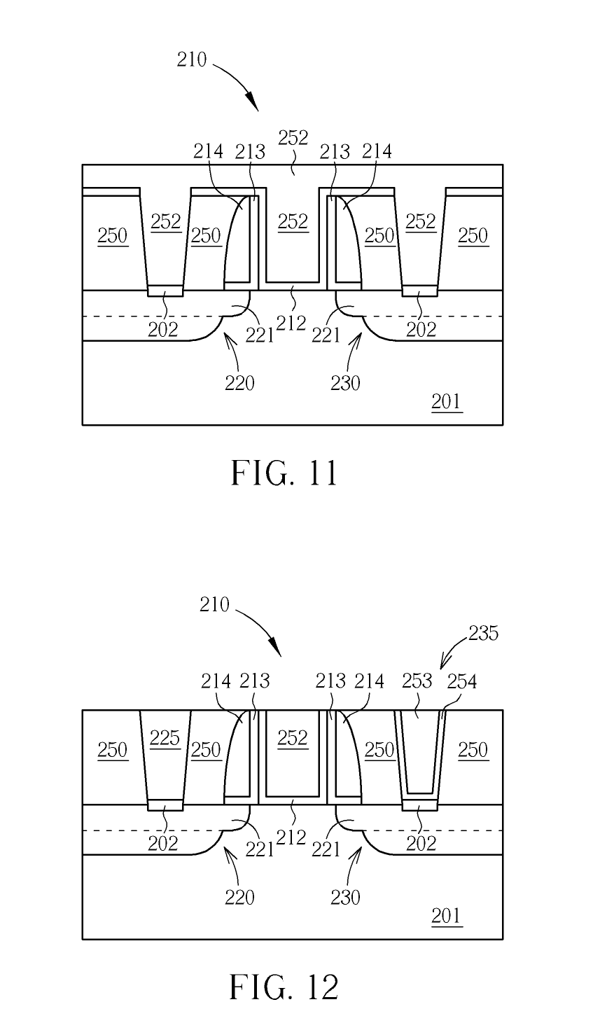

After that, the dummy gate 211 is removed and the removal may stop on an optional metal etching barrier layer or on the gate dielectric layer 212. Different ways should be used to remove the dummy gate 211 depending on different materials. When Si is used as the dummy gate 211, tetramethylammonium hydroxide (TMAH) or aqueous ammonia may be used. However, other methods to remove the dummy gate 211 are known by persons of ordinary skills in the art so the details will not be described here. Next, a suitable material refills to replace the dummy gate 211 to form a gate material layer 215 and a gate dielectric layer 212. Optionally, if the gate dielectric layer 212 is formed just before the formation of the gate material layer 215, the resultant gate dielectric layer 212 should be in a U-shape, as shown in FIG. 11. The gate material layer 215, such as a P-type or an N type work function material, of the present invention is in particular suitable for use in a metal gate. The pad oxide layer and the pad oxynitride layer may be removed when the dummy gate 211 is removed.

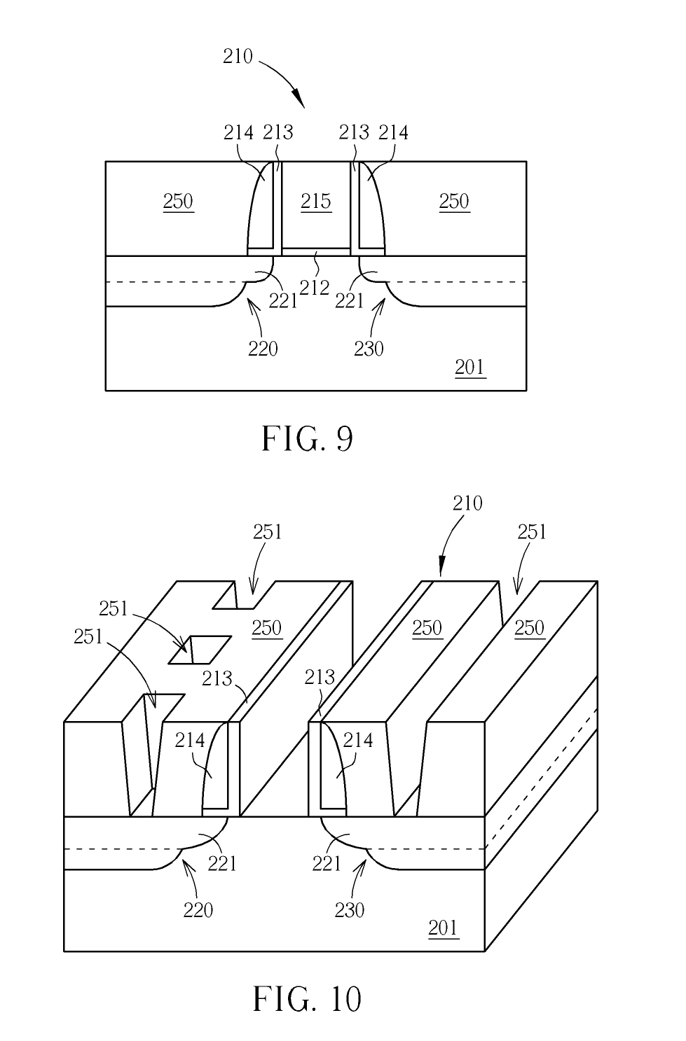

The replacement of the dummy gate 221 by a suitable material may be related to the formation of the silicide or not. For example, as shown in FIG. 9, if the replacement of the dummy gate 211 by a suitable material has nothing to do with the formation of the silicide, a suitable material refills after the dummy gate 211 is removed to form a metal gate to replace the dummy gate 211 when the dummy gate 211 is exposed. The metal gate includes a gate material layer 215 and a gate dielectric layer 212. The gate dielectric layer 212 may be an insulting material of high dielectric constant, such as La₂O₃, Ta₂O₅, TiO₂, HfO₂, ZrO₂, Al₂O₃, La₂O₃ or Pr₂O₃. The gate material layer 215 is a suitable metal such as Ti, TiN, Co, Ni, Pt or Ir, or a metal nitride, or a metal carbide. If the pad oxide layer and the pad oxynitride layer are not removed, there are the pad oxide layer and the pad oxynitride layer which are disposed under the gate dielectric layer 212 present in the final structure.

On the other hand, if the replacement of the dummy gate 211 is related with the formation of the silicide, the dummy gate 211 may be first removed then the interlayer dielectric layer 250 is selectively removed to form the needed contact holes 251, or the interlayer dielectric layer 250 is selectively removed before the dummy gate 211 is removed, as shown in FIG. 10. The removal of the dummy gate 211 may stop on an optional metal etching barrier layer or on the gate dielectric layer 212. If any stress layer or etching-stop layer is present, the contact holes 151 penetrate the stress layer or the etching-stop layer as well to expose the source 220 and drain 230 under the interlayer dielectric layer 250 to form the later needed electrical connection. FIG. 10 illustrates an example when both the stress layer and the etching-stop layer are absent. The steps to form the contact holes 251 may be that, a lithographic procedure goes with an etching procedure to obtain the contact holes 251 of needed shapes or sizes. For example, the contact holes 251 may be in a shape of a single square or of a slot. In addition, the shape of the contact holes 251 of the source and drain may be different, and the size of the contact holes 251 of the source and drain may be different, too.

Later, as shown in FIG. 11, the gate dielectric layer 212 first replaces some of the dummy gate 211, then a suitable metal replaces the removed dummy gate 211. Now the metal can react with the substrate 201 to form the needed silicide 202. The ways to form the needed silicide 202 may be that, first, a suitable contact metal 252, such as Ni, Co or Ti, is used to fill the contact holes 251 under a suitable temperature and a suitable pressure by a physical vapor deposition (PVD) or an electrodeless plating so that the contact metal 252 is in direct contact with the source 220 and the drain 230. At the moment, the contact metal 252 also replaces some of the dummy gate 211. Then, an annealing step is carried out to react the contact metal 252 with the substrate 201 to yield the silicide 202. Some of the contact metal 252 now becomes the metal gate. The metal used for the silicide formation may not be removed after the silicide is formed. A chemical mechanical polishing may be used to remove the residuary metal and render the metal remaining in the contact holes as local interconnect.

In another embodiment of the present invention, the unreacted contact 252 in the contact holes is removed after the silicide 202 is finished, a source contact plug 225 and a drain contact plug 235 are formed in the contact holes 251, as shown in FIG. 12. The source contact plug 225 and the drain contact plug 235 are respectively disposed in the contact holes 251 and in direct contact with the previously formed silicide 202. The ways to form the source contact plug 225 and the drain contact plug 235 may be that, for example, a suitable plug metal 253, such as W, is used to fill the contact holes 251. Optionally, at least two plug materials such as a plug metal 253 and a barrier material 254, are used to form one of the source contact plug 225 and the drain contact plug 235. The forming parameters for the barrier material 254, such as materials, thickness may be adjusted to form a maximized stress effect. The plug material to fill the source/drain may be the same or different.

Those skilled in the art will readily observe that numerous modifications and alterations of the device and method may be made while retaining the teachings of the invention.

1. A method for forming silicide for use in a contact plug, comprising:
providing a substrate;
forming a gate structure comprising a silicon layer, a gate dielectric layer and at least one spacer on said substrate;
forming a pair of source and drain in said substrate and adjacent to said gate structure;
forming an interlayer dielectric layer to cover said gate structure, said source and said drain;
selectively removing said interlayer dielectric layer to expose said gate structure;
forming a plurality of contact holes in a shape of a slot and in said interlayer dielectric layer to expose part of said substrate, wherein said slot has a short side and a long side which extends in a direction parallel with a gate width;
converting said substrate exposed by said contact holes to silicide; and
filling said contact holes to form at least one of a source contact plug and a drain contact plug.

2. The method for forming silicide for use in a contact plug of claim 1, wherein at least said spacer is removed before said interlayer dielectric layer is formed.

3. The method for forming silicide for use in a contact plug of claim 1, further comprising:
filling said contact holes with a contact metal which is in direct contact with said source and said drain; and
performing an annealing step to react said contact metal with said substrate to form said silicide.

4. The method for forming silicide for use in a contact plug of claim 1, before said interlayer dielectric layer is formed further comprising
forming an etching-stop layer to cover said gate structure, said source and said drain so that said contact holes penetrate said etching-stop layer to expose said source and said drain.

5. The method for forming silicide for use in a contact plug of claim 1, wherein a chemical mechanical polishing procedure is used to selectively remove said interlayer dielectric layer.

6. The method for forming silicide for use in a contact plug of claim 1, wherein a source contact plug and a drain contact plug are formed in said contact holes and in direct contact with said silicide.

7. The method for forming silicide for use in a contact plug of claim 1, wherein at least one of said source and said drain comprises a recessed structure.

8. The method for forming silicide for use in a contact plug of claim 3, wherein said annealing step is performed to react said contact metal with said gate structure to form said silicide.

9. The method for forming silicide for use in a contact plug of claim 3, wherein a chemical mechanical polishing procedure is used to remove said contact metal after said annealing step.

10. The method for forming silicide for use in a contact plug of claim 1, wherein at least two plug materials which are selected from a plug metal and a barrier material are used to form one of said source contact plug and said drain contact plug.

11. A method for forming silicide for use in a contact plug, comprising:
providing a gate structure disposed on a substrate and comprising a dummy gate;
forming a pair of source and drain in said substrate and adjacent to said gate structure;
forming an interlayer dielectric layer to cover said source and said drain and to expose said gate structure;
selectively removing said dummy gate;
forming a plurality of contact holes in a shape of a slot and in said interlayer dielectric layer to expose said source and said drain, wherein said slot has a short side and a long side which extends in a direction parallel with a gate width;
filling said contact holes with a contact metal which is in direct contact with said source and said drain; and
performing an annealing step to react said contact metal with said substrate to form said silicide.

12. The method for forming silicide for use in a contact plug of claim 11, before said contact holes are formed further comprising:
forming a metal gate which comprises a gate metal and a gate dielectric layer to replace said dummy gate.

13. The method for forming silicide for use in a contact plug of claim 11, wherein said contact metal is used to replace said dummy gate to form a metal gate which comprises a gate metal and a gate dielectric layer.

14. The method for forming silicide for use in a contact plug of claim 13, wherein said contact metal fills said contact holes and forms said metal gate at the same time.

15. The method for forming silicide for use in a contact plug of claim 11, wherein a chemical mechanical polishing procedure is used to selectively remove said interlayer dielectric layer and to expose said gate structure.

16. The method for forming silicide for use in a contact plug of claim 11, wherein at least one of a physical vapor deposition (PVD) and an electrodeless plating is used to fill said contact metal under a suitable temperature and a suitable pressure.

17. The method for forming silicide for use in a contact plug of claim 11, wherein at least one of said source and said drain comprises a recessed structure.

18. The method for forming silicide for use in a contact plug of claim 11, wherein a chemical mechanical polishing procedure is used to remove said contact metal.

19. The method for forming silicide for use in a contact plug of claim 11, wherein at least two plug materials which are selected from a plug metal and a barrier material are used to form one of said source contact plug and said drain contact plug.

20. (canceled)

21. The method for forming silicide for use in a contact plug of claim 11, further comprising:
forming said source/drain contact plug disposed in one of said contact holes and in direct contact with said silicide.
